(19) United States
(12) Patent Application Publication
(10) Pub. No.: US 2014/0328039 A1
(43) Pub. Date: Nov. 6, 2014

(54) SYSTEMS AND METHODS FOR VOID REDUCTION IN A SOLDER JOINT

(71) Applicant: ALPHA METALS, INC., South Plainfield, NJ (US)

(72) Inventors: Paul J. Koep, Madison, NJ (US); Michiel A. de Monchy, Utrecht (NL); Ellen S. Tormey, Princeton Junction, NJ (US)

(21) Appl. No.: 14/347,035

(22) PCT Filed: Sep. 25, 2012
(86) PCT No.: PCT/US12/57116

§ 371 Date: Mar. 25, 2014

Related U.S. Application Data
(60) Provisional application No. 61/539,260, filed on Sep. 26, 2011.

(51) Int. Cl. H05K 13/04; H05K 1/09; H05K 1/11; H01L 23/00

(52) U.S. Cl. CPC H05K 13/0465; H01L 24/81; H01L 24/11; H01L 24/17; H05K 1/092; H05K 1/111; H01L 2924/014; H01L 2924/2076; H01L 2924/14; H01L 2224/1624; H01L 2224/9201; H01L 2224/812; H01L 2224/81801; H01L 2224/16113
USPC 361/767; 174/260; 174/257; 228/226; 228/56.3

(57) ABSTRACT

In accordance with one or more aspects, a method of reducing void formation in a solder joint may comprise applying a solder paste deposit to a substrate, placing a solder preform in the solder paste deposit, disposing a device on the solder preform and the solder paste deposit, and processing the solder paste deposit and the solder preform to form the solder joint between the device and the substrate. In some aspects, the substrate is a printed circuit board and the device is an integrated circuit package.

### FIELD OF THE INVENTION

One or more aspects relate generally to solder joints, and more particularly, to systems and methods for void reduction in solder joints.

### BACKGROUND

Integrated circuit packages are typically soldered to a substrate, such as a printed circuit board, in the manufacture of high performance electronic assemblies. Voiding in the solder joints may result during processing of the assemblies. Excess voiding may lead to increased power consumption, increased operating temperature, reduced electrical performance, and an overall failure of the integrated circuit packages to reach their expected lifespan.

### SUMMARY

In accordance with one or more aspects, a method of reducing void formation in a solder joint may comprise applying a solder paste deposit to a substrate, placing a solder preform in the solder paste deposit, disposing a device on the solder preform and the solder paste deposit, and processing the solder paste deposit and the solder preform to form the solder joint between the device and the substrate.

In some aspects, the substrate is a printed circuit board and the device is an integrated circuit package. The processing step may comprise heating the solder paste deposit and the solder preform to a temperature in a range of about 140° C. to about 275° C. The method may further comprise placing a second solder preform in the solder paste deposit. The solder paste deposit may be applied in a thickness greater than or equal to a thickness of the solder preform. Applying the solder paste deposit to the substrate comprises printing the solder paste in a pattern on the substrate. A diameter of the solder preform may be between about 1 mm and about 15 mm. A thickness of the solder preform may be between about 0.025 mm and about 0.2 mm. The solder preform may comprise at least about 99.9% by weight a pure metal or a pure metal alloy. The pure metal or the pure metal alloy may comprise at least one of tin, silver, antimony, copper, lead, nickel, indium, palladium, gallium, cadmium, and bismuth. In some aspects, the solder preform is substantially free of flux. In at least certain aspects, the solder joint may be characterized by a void space of less than about 40% by area. The solder preform may contribute about 25% to about 95% of the solder joint by volume after reflow.

In accordance with one or more aspects, an assembly may comprise a printed circuit board, a device bonded to the printed circuit board, and a solder joint between the printed circuit board and the device. About 25% to about 95% of the solder joint by volume comprises a solder preform after reflow.

In some aspects, the solder joint comprises at least one of tin, silver, antimony, copper, lead, nickel, indium, palladium, gallium, cadmium, and bismuth. The solder joint may be characterized by a void space of less then about 40% by area.

In accordance with one or more aspects, a kit for assembling a device to a printed circuit board may comprise a solder paste and at least one solder preform having a diameter between about 1 mm and about 15 mm and a thickness between about 0.025 mm and 0.2 mm, the at least one solder preform comprising at least about 99.9% by weight a pure metal or a pure metal alloy.

In some aspects, the at least one solder preform is disposed on tape and reel packaging. In other aspects, the at least one solder preform is disposed on a tray for pick and place treatment. In still other aspects, the at least one solder preform is packaged in automated and/or machine-ready packaging.

In accordance with one or more aspects, a method of facilitating void reduction in a solder joint may comprise providing a solder preform and providing instructions to apply the solder preform to a solder paste deposit on a printed circuit board prior to reflow to form the solder joint.

In some aspects, the method may further comprise providing solder paste.

In accordance with one or more aspects, a solder joint between a printed circuit board and an integrated circuit package may be characterized by a void space of less then about 40% by area, wherein about 25% to about 95% of the solder joint by volume comprises a solder preform after reflow.

Still other aspects, embodiments, and advantages of these exemplary aspects and embodiments, are discussed in detail below. Moreover, it is to be understood that both the foregoing information and the following detailed description are merely illustrative examples of various aspects and embodiments, and are intended to provide an overview or framework for understanding the nature and character of the claimed aspects and embodiments. The accompanying drawings are included to provide illustration and a further understanding of the various aspects and embodiments, and are incorporated in and constitute a part of this specification. The drawings, together with the remainder of the specification, serve to explain principles and operations of the described and claimed aspects and embodiments.

### BRIEF DESCRIPTION OF THE DRAWINGS

Various aspects of at least one embodiment are discussed below with reference to the accompanying figures. The figures are provided for the purposes of illustration and explanation only and are not intended as a definition of the limits of the invention. In the figures:

FIGS. 1A presents a schematic of a patterned solder paste deposit in accordance with one or more embodiments;

FIG. 1B presents a schematic of a solder preform disposed on a substrate relative to the solder paste deposit of FIG. 1A in accordance with one or more embodiments;

FIGS. 2A and 2B present schematics of a solder joint assembly prior to reflow in accordance with one or more embodiments;

FIG. 3 presents a leadless package assembly in accordance with one or more embodiments;

FIG. 4 presents data discussed in accompanying Example 1 in accordance with one or more embodiments; and

FIG. 5 presents a schematic of a flux coated preform discussed in accompanying Example 2 in accordance with one or more embodiments.

### DETAILED DESCRIPTION

In accordance with one or more embodiments, voiding in solder joints may be reduced while maintaining the strength of the solder joints. Void reduction may improve the integrity and lifespan of integrated circuit packages in electronic assemblies. Beneficially, void reduction in solder joints may improve heat dissipation and decrease power consumption of integrated circuit packages. Improved electrical performance may be recognized. The reliability of integrated circuit packages may also be improved. Cost savings may also be recognized by decreasing the number of integrated circuit packages which require either disposal or rework during an assembly operation. In accordance with one or more embodiments, existing systems and methods for the manufacture of electronic assemblies may be easily retrofitted to facilitate void reduction in solder joints. In accordance with one or more embodiments, solder preforms may be used to reduce voiding in solder joints. In some nonlimiting embodiments, a solder joint may be characterized by a void space of less than about 50% by area. In at least some nonlimiting embodiments, a solder joint may be characterized by a void space of less than about 35%.

In accordance with one or more embodiments, a first element may be bonded to a second element to form a joint therebetween. In some embodiments, the first element may be an integrated circuit package and the second element may be a substrate, such as a printed circuit board (PCB). Other substrates may be implemented. In certain embodiments, an electronic assembly may generally include at least one integrated circuit package bonded to a PCB. Some electronic assemblies may include a plurality of integrated circuits bonded to a PCB. An integrated circuit package may be any electronic device or package such as, but not limited to, a Land Grid Array (LGA), Duel Flat No leads (DFN), Quad Flat Package (QFP), Quad Flat No leads (QFN), Low-Profile Quad Flat Package (LQFP) and MicroLeadFrame (MLF). In at least one alternative embodiment, the first and second elements may instead be first and second elements of an integrated circuit package or other component to be assembled. Other first and second elements may be implemented in accordance with various embodiments relating to void reduction.

In accordance with one or more embodiments, a first element may be bonded to a second element using a variety of materials, such as adhesives, resins or solders. Solder paste is typically used to bond integrated circuit packages to a substrate, such as a PCB. Solder paste may typically include a metal or a metal alloy. Solder paste may also generally include one or more soldering agents known as flux. Flux may include one or more chemical cleaning and wetting agents. As a cleaning agent, flux may facilitate soldering by removing oxidation species from surfaces of metals to be joined. As a wetting agent, flux may facilitate solder flow on a work piece, inhibiting bead formation and effectively wetting surfaces of the work piece.

A solder paste deposit is typically applied between a PCB and an integrated circuit package. The solder paste deposit may be processed to form a solid bond between the integrated circuit package and the PCB, thus forming an electronic system or an electronic assembly. Processing may generally involve a cooling, heating or reflow process. During the bonding and cooling process, gas may become trapped, such as may be due to out-gassing of a flux component of the solder paste. Without wishing to be bound by any particular theory, trapped out-gassing may form one or more voided regions in a solder joint. The sandwiching of solder paste between the PCB and an integrated circuit package may also result in voided regions in the solder joint. Voiding is often tolerated but undesirable.

Integrated circuit packages generally produce heat while in operation. If the integrated circuit package is not able to efficiently dissipate heat, then it may undergo a decrease in performance or suffer thermal damage. Many integrated circuit packages make use of a heat path, such as one associated with its bottom surface, to dissipate heat. The heat path may sometimes include a thermal pad. Thermal pads may be soldered to the PCB, providing a mechanism for transferring heat from the integrated circuit package to a ground plane of the PCB. Bonding the integrated circuit package to the PCB therefore facilitates the transfer of heat from the integrated circuit package to the PCB along a flow path. Adhesive resins and solder typically have good thermal conductivity and function to transfer heat from the integrated circuit package to the PCB. Additionally, solder has good electrical conductivity which helps to electrically ground an integrated circuit package. Without wishing to be bound to any particular theory, void formation may impair at least one of the thermal conductivity and the electrical conductivity of a joint between an integrated circuit package and a PCB. The integrated circuit can also experience reduced electrical performance of high frequency signals as a result of poor electrical ground integrity.

Industrial assembly line equipment and methods provide a mechanized process for efficiently producing large numbers of electronic assemblies. While some degree of voiding in solder joints may be tolerated, the presence of excess voiding in solder joints between a mounted integrated circuit package and a PCB, however, may cause many assemblies to fail to meet one or more operational specifications, or industry standards such as those set by the IPC (Association Connecting Electronics Industries) or other relevant standards-setting organizations. Such a failure due to excess voiding may result in a number of increased manufacturing expenses attributable to rework, component scrap rates, and PCB scrap rates. In specific cases relating to high-end components expected to have a relatively long life span, one or more embodiments relating to reduced void formation may provide a relatively low cost assurance that such components will operate for its expected life span. In other embodiments where the expected life span of a component may be relatively short, void reduction nevertheless may provide benefits by lowering the associated power dissipation of an integrated circuit package. Where the integrated circuit package is powered by a battery, such as in a mobile phone, lower power dissipation results in longer battery life. Thus void reduction may have a useful application relevant to battery-powered integrated circuit technologies, specifically, or to efforts to conserve power consumption, generally. A repeatable, systematic approach to void reduction in accordance with one or more embodiments is therefore capable of improving overall efficiency in the manufacturing process on a number of levels.

In accordance with one or more embodiments, systems and methods for reducing void space formed in a solder joint may involve use of one or more solder preforms. In some embodiments, a combination of solder paste and one or more solder preforms may be used. In at least one embodiment, an amount of flux in a molten solder joint may be reduced. In some embodiments, at least one preform may be used to replace at least a portion of solder paste in a solder joint prior to reflow to reduce the amount of flux present. In some embodiments, reduction of solder paste and the addition of a preform may systematically reduce voiding. The integrity and strength of the solder joint may be maintained. In some embodiments, the relative amount of solder paste and preform present in a solder joint prior to reflow may be selected to ensure the integrity of the solder joint while achieving a desired reduction in void formation.

In accordance with one or more embodiments, resulting solder joints may have reduced void space. Furthermore, systems and methods in accordance with one or more embodiments can be applied on an industrial scale without requiring the purchase of new capital equipment. Instead, existing manufacturing systems and methods may be retrofitted in accordance with one or more embodiments. For example, preforms may be placed onto tape and reel packaging or a pick and place tray, allowing the preforms to be easily incorporated into standard automated processes. The use of solder paste in conjunction with one or more preforms may facilitate anchoring. Use of one or more preforms in conjunction with solder paste as discussed herein may serve to fixture or anchor the preforms, keeping both the preform and the integrated circuit package in place such as during travel along an assembly line.

Certain aspects and examples disclosed herein provide methods, assemblies, and kits for reducing void space in solder joints or otherwise facilitating the reduction thereof. One or more embodiments relate to systems and methods for void reduction. Some specific embodiments relate to systems and methods for reducing void formation which implement both solder paste and a solder preform to form a solder joint. At least certain embodiments relate to a method of reducing void formation in a solder joint through the combined use of solder paste and solder preform. Some nonlimiting embodiments relate to an assembly including an integrated circuit package bonded to a PCB by a solder joint. The solder joint, prior to processing or reflow, may include solder paste and at least one solder preform. Other nonlimiting embodiments may relate to a kit for assembling an integrated circuit package to a PCB. The kit may include solder paste and at least one solder preform. Void reduction in a solder joint may be facilitated by providing a solder preform and instructions for applying a solder preform to a solder paste deposit on a printed circuit board prior to processing or reflow to form the solder joint.

In accordance with one or more embodiments, a method of reducing void formation in a solder joint may involve applying a solder paste deposit to a substrate. The substrate may be, for example, a PCB. Any solder paste may be used depending on an intended application. A solder paste, as discussed above, may generally include one or more metals or metal alloys, and one or more flux agents. In some embodiments, the solder paste may include at least one of tin, silver, antimony, copper, lead, nickel, indium, palladium, gallium, cadmium, and bismuth. In some nonlimiting embodiments, a material of the solder paste may generally be the same as a material of a preform to be disposed in the solder paste, although that is not strictly necessary. In some nonlimiting embodiments, any solder paste commercially available from Cookson Electronics may be used. Nonlimiting examples of alloys which may be used in the solder paste and/or the preforms discussed herein include: Sn/Ag/Cu; Sn/Ag/Cu/Ni; Sn/Ag/Cu/Ni/Bi; Sn/Ag; Sn/Ag/Cu/Bi; Sn/Bi; Sn/Bi/Ag; Sn/Bi/Ag/Ni; Sn/Bi/Ag/Cu; Sn/Pb; Sn/In; and Sn/Pb/Ag.

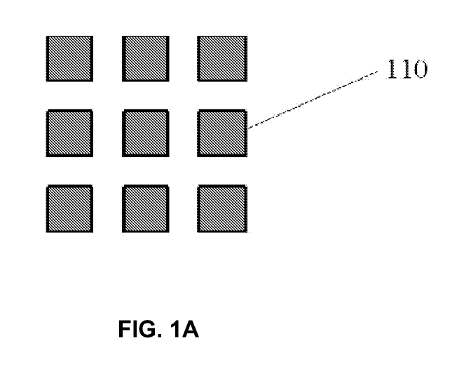

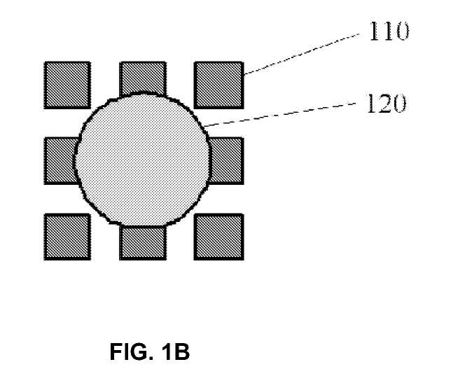

In accordance with one or more embodiments, the solder paste may be applied to the substrate with various known techniques, such as a printing method. In some embodiments, the solder paste may be applied as a single deposit. The dimensions and/or volume of the deposit on the substrate may correspond to the size of an integrated circuit package to be bonded to the substrate or to the size of an intended resulting solder joint. In some nonlimiting embodiments, the volume of the solder paste deposit may be about twice the volume of a resulting solder joint after processing. In other embodiments, the solder paste may be applied in any desired pattern rather than in a single deposit. A stencil or other technique may be used to create a desired pattern. For example, the solder paste 110 may be applied in a lattice pattern or a window pattern as illustrated in FIG. 1A. In some nonlimiting embodiments, solder paste may be deposited in a pattern that generally matches the pattern of conductive contacts embedded in a substrate, such as a PCB. Without wishing to be bound by any particular theory, patterning of solder paste may reduce the overall volume of solder paste used and provide a path for out-gassing of volatile flux present in the solder paste during processing which may contribute to reduction of void formation. The solder paste may be applied in any desired thickness. In at least some embodiments, the thickness of a solder paste deposit may generally be greater than or equal to a thickness of a preform to be placed into the solder paste deposit. In some nonlimiting embodiments, one or more preforms may be inserted to contribute a volume left void by an applied solder paste pattern. Stencil thickness may depend on a desired solder height and may be impacted by component pitch, aspect ratio and other factors. In some embodiments, it may be desirable to print solder paste at the corners of a large thermal pad and to insert one or more preforms towards the center of the thermal pad. A base layer may also be applied under the preforms.

In accordance with one or more embodiments, one or more solder preforms may then be placed in the solder paste deposit on the substrate. A solder preform may include one or more metals or metal alloys depending on an intended application. A solder preform may generally be a preformed solid rather than, for example, a solder paste. Some examples of metals that may be used in a preform include but are not limited to tin, silver, antimony, copper, lead, nickel, indium, palladium, gallium, cadmium and bismuth. A solder preform may be of any size and shape depending on an intended application. In some embodiments, a preform may generally be disc-shaped. A preform may have any desired thickness. In some embodiments, a preform may be generally thinner than a deposit of solder paste into which it is placed. The preform may be thin enough to fit under a component or device to be bonded to a substrate. In some nonlimiting embodiments, a thickness of a preform may be between about 0.025 and 0.2 millimeters. Likewise, a preform may be of any desired diameter. In some embodiments, dimensions of an integrated circuit package to be bonded, or a characteristic of a substrate to be used, may impact the size of the preform. In some nonlimiting embodiments, a disc-shaped preform may have a diameter between about 1 and 15 mm. In some embodiments, an implemented preform may be any Alpha® ExactaHoy® solder preform commercially available from Cookson Electronics.

In accordance with one or more embodiments, a solder preform may be substantially free of flux. In some nonlimiting embodiments, a solder preform may be at least 99% pure metal or pure metal alloy. In some embodiments, a solder preform may be about 99.9% pure metal or pure metal alloy. In at least some embodiments, a solder preform may be about 99.99% pure metal or pure metal alloy. In accordance with one or more embodiments, rather than contain flux, a solder preform may rely on flux present in surrounding solder paste to support processing or reflow. Thus, the integrity and strength of a solder joint may be maintained while reducing voiding. In some specific nonlimiting embodiments, a substantially flux-free preform may be complexed with a solder paste flux coating. A preform may be coated with flux solids. Without wishing to be bound by any particular theory, such a coating may ensure complete reflow of the preform and also provide a robust low void connection of an integrated circuit package to a substrate post-processing. Thus, as an alternative to the combined use of a solder preform and solder paste, void reduction may also be accomplished in some nonlimiting embodiments by coating preforms with flux. In general, it may be desirable to minimize the amount of flux coating on the preforms to minimize voids. Since preforms have much lower surface area than solder powder used in pastes, much less flux may be required for effective soldering. In such nonlimiting examples where solder paste might not be used in conjunction with the preforms, the preforms may instead be fixtured, anchored or held in place by, for example, leads extending from the integrated circuit package to the PCB. In some embodiments, leads of the integrated circuit package may be placed in solder paste and a flux coated preform may be placed in contact with a thermal pad of the integrated circuit package prior to processing. In accordance with one or more embodiments, a preform may be flux coated. Flux coated, tape and reel preforms may be generally implemented in accordance with one or more embodiments.

In some nonlimiting embodiments, a single preform may be placed into the center of a solder paste deposit. In other embodiments, a single solder preform may generally be offset. In some embodiments, two or more preforms may be used in a single solder paste deposit. In other embodiments, a solder preform may be placed into each component of a solder paste pattern. The number and positioning of the solder preforms relative to the solder paste deposit may generally depend on factors such as the patterning of the solder paste deposit, as well as the size of an integrated circuit package to be bonded in the assembly. FIG. 1B shows solder paste 110 applied in the “window pane” pattern with a preform 120 placed into the solder paste. Without wishing to be bound by any particular theory, the solder paste may serve to hold or fix the preform(s) in place to avoid shifting during processing. In some embodiments, leads or legs associated with an integrated circuit package may help to align the assembly such that the integrated circuit package may be anchored to the PCB.

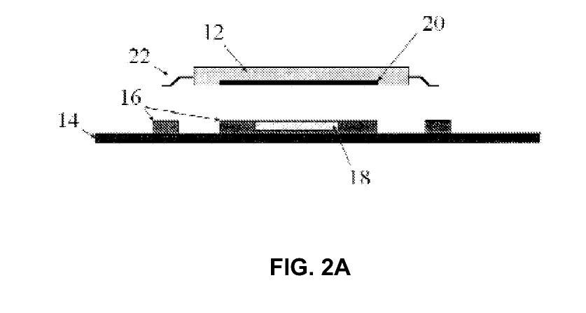

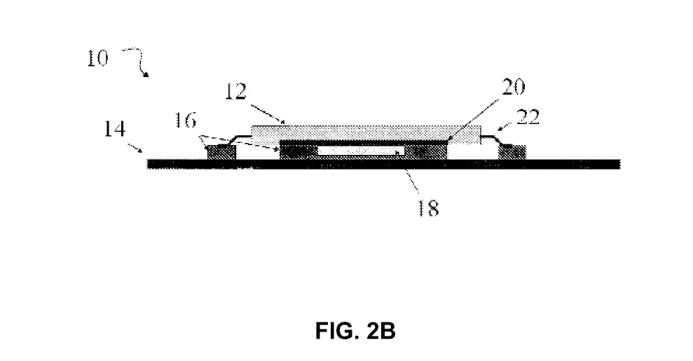

In accordance with one or more embodiments, a component or a device, such as an integrated circuit package, may then be disposed on the deposited solder paste and preform. In some embodiments, the device may be disposed on a combination of solder paste and preform prior to reflow. The solder joint components, prior to reflow, may therefore be sandwiched between the substrate and the component to be bonded. FIGS. 2A and 2B show side-views of assemblies prior to reflow in accordance with one or more embodiments. FIG. 2A illustrates the positioning of various components prior to disposing a device onto the combination of solder paste and solder preform. FIG. 2B shows the positioning of the components of FIG. 2A prior to the processing step. An assembly, generally indicated at 10 of FIG. 2B, includes a printed circuit board 14. A deposit of solder paste 16 is applied to the printed circuit board 14. Disposed on the solder paste 16 is a solder preform 18. An integrated circuit package 12 is applied to the solder paste 16 and solder preform 18. A thermal pad 20 of the integrated circuit package 12 is in contact with at least the solder paste 16. Solder paste 16 is also in contact with lead wires 22 which may be associated with integrated circuit package 12. The preform 18 may be thin enough to fit under the package 12. After processing as discussed below, the solder paste 16 and solder preform 18 will form a solder joint that bonds the integrated circuit package 12 to the printed circuit board 14. In some preferred embodiments, about 25% to about 95% of a solder joint by volume may comprise a solder preform after reflow.

In accordance with one or more embodiments, the assembly may then be processed to form a solder joint between the integrated circuit package and the substrate, such as a PCB. Processing may generally involve heating and/or cooling. The solder preform may be heated so as to melt and complex with the solder paste, then cooled to form a solid solder joint between the substrate and integrated circuit package. The processing step may comprise heating the solder paste deposit and the solder preform to a temperature in a range of about 140° C. to about 275° C. in some nonlimiting embodiments. The solder may then cool and solidify forming a solid bond.

In accordance with one or more nonlimiting embodiments, preform thickness may dictate an interaction between the solder paste and the device. In some embodiments, a component thermal pad may not come in contact with flux until the preform collapses depending on a thickness of the preform. This may reduce the contact time such that there is less opportunity for the flux in solder paste to deoxidize the thermal pad. In some embodiments involving components with leads, a relatively thin preform may be used in conjunction with solder paste, and the component leads can still come into contact with printed paste, thus anchoring the component to the PCB prior to reflow with both lead-solder paste contact as well as thermal pad-solder paste contact.

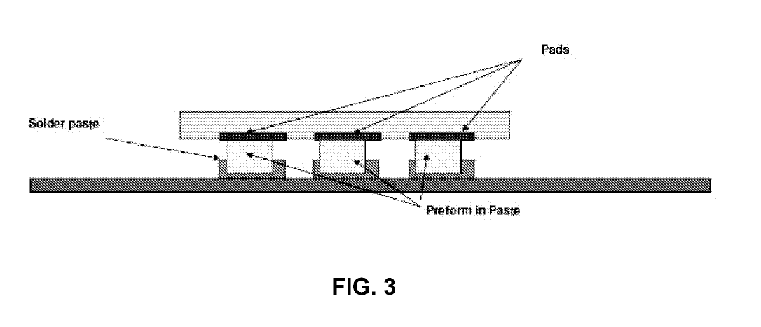

In such embodiments, the use of a preform that is thicker than the solder paste may be problematic because the leads of the component would not come in contact with solder paste, and misalignment of the leads and the pads with solder paste after processing may be likely. In some embodiments involving leadless packages as illustrated in FIG. 3, however, such as an LGA, which contain only a number of pads on the bottom surface, preforms that are thicker than the solder paste deposit may be used while still achieving both reduced voiding and proper component-PCB alignment after reflow. This can be achieved with relatively crude fixturing. If the orientation of the component pads is maintained relative to the board pads with fixturing, during processing, the preforms will collapse into molten solder, and the component will be lowered onto the board pads. There is an amount of self aligning that occurs whereby the component tends to orient itself due to capillary action and wetting action of the solder onto the component pads. With only surface mount pads to consider, the fixturing can be relatively inexpensive yet adequate to achieve acceptable component position post processing.

In accordance with one or more embodiments, an assembly may include a printed circuit board, a component or device bonded to the printed circuit board, and a solder joint bonding the printed circuit board and the device. In accordance with one or more embodiments, about 25% to about 95% of a solder joint by volume may be composed of a solder preform after reflow or processing. Measurable reductions in void space may be detected with the use of solder preforms to replace at least a portion of solder paste in a solder joint prior to processing. In some nonlimiting embodiments, solder preform may constitute as little as 10% of a solder joint by volume after reflow. In some embodiments, the solder preform may contribute about 25% to about 95% of the solder joint by volume prior to reflow. In other embodiments, the solder preform may contribute about 25% to about 80% of the solder joint by volume after reflow. In still other embodiments, the solder preform may contribute about 50% to about 80% of the solder joint by volume after reflow. In some nonlimiting embodiments, a solder joint formed in accordance with one or more embodiments may be characterized by a final void space of less than about 50% by area. In still other embodiments, a solder joint may be characterized by a final void space of less than about 40% by area. In some embodiments, a solder joint may be characterized by a final void space of less than about 35% by area. In some nonlimiting embodiments, a solder joint may have a final void space of less than about 30% by area. In at least some embodiments, a solder joint may have a final void space of less than about 20% by area. In certain nonlimiting embodiments, a solder joint may have a final void space of less than about 10% by area. Void space may be measured by x-ray photograph of the solder joint or by other imaging techniques. In some embodiments, a fraction of total area of a solder joint that is void may be generally representative of the void space percentage by area of the solder joint.

In accordance with one or more embodiments, prior to incorporation into a solder joint, preforms may be disposed on different forms of packaging that facilitate the automated placement of the preforms onto substrates, such as printed circuit boards. For example, the preforms may be placed onto tape and reel packaging, or a pick and place tray.

The above aspects are not limited to applications where an integrated circuit package is joined to a PCB. As discussed above, various first and second elements may be bonded with the techniques discussed herein. For example, in some nonlimiting embodiments the combination of a preform and solder paste may be used to join components of a single integrated circuit package. A soldered joint within an integrated circuit package may be desirably characterized by low voiding and an ability to withstand reflow during subsequent processing to join the integrated circuit package to a substrate. Withstanding this subsequent heating process can be accomplished by, for example, increasing the lead content of the solder joint within the integrated circuit package through selection of appropriate solder paste and solder preform alloys.

In accordance with one or more embodiments, a kit for assembling a device to a printed circuit board may be provided. A kit may include solder paste and at least one solder preform. In some nonlimiting embodiments, a preform may have a diameter between about 1 mm and about 15 mm and a thickness between about 0.025 mm and 0.2 mm. In certain nonlimiting embodiments, the solder preform may be at least about 99.9% by weight pure metal or pure metal alloy, the remaining 0.1% consisting of impurities and trace elements. In at least one embodiment, the solder preform may be at least about 99.99% by weight pure metal or pure metal alloy, the remaining 0.01% consisting of impurities and trace elements. High purity metal or metal alloys may improve voiding performance because impurities interfere with joint formation by, for example, disturbing wetting. The kit may also include instructions to apply the solder preform to a solder paste deposit on a printed circuit board prior to reflow to form a solder joint.

In accordance with one or more other embodiments, a method of facilitating void reduction in a solder joint may include providing a solder preform, and providing instructions to apply the solder preform to a solder paste deposit on a printed circuit board prior to reflow to form the solder joint.

### EXAMPLE 1

An experiment was conducted with components having 30 mm² thermal pads and with a 0.05-0.10 mm standoff from the board and 2 or 4 mm preforms. FR4 glass epoxy printed circuit boards of typical thickness, about 0.062 inches were used. The board finish was organic surface protectant (OSP). The solder paste used was SAC305 Type 4 powder. The disc shaped preforms were SAC305 alloy with dimensions 4mm diameter with 0.1 mm thickness and 2mm diameter with 0.1mm thickness. The reflow profiles used were both straight ramp (temperature vs. time) and soak profile, typical of those used in the industry. The paste patterns printed included 100% coverage without preforms (control) as well as various window pane patterns of printed solder paste that had coverage of 50% down to <20% of the pad area. Corresponding to the 50% coverage, small preforms that resulted in 45% of the solder joint volume were used. Corresponding to the <20% coverage, a larger preform which resulted in significantly higher percentage of the solder joint (>80%) was used.

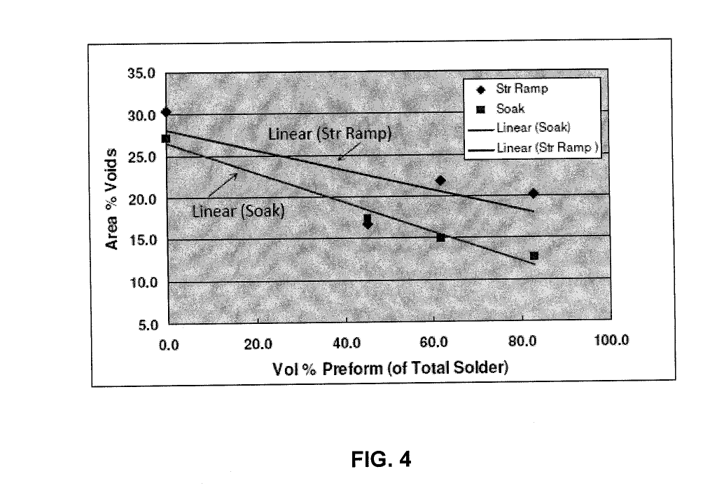

FIG. 4 presents the results of experiments involving the combined use of a preform with solder paste to reduce void formation. The y-axis represents the percentage by area of void formation to total area of solder joint. The x-axis represents the percentage by volume of solder preform in the total solder joint after processing. The trend lines indicate a relationship between an increase in relative volume of preform and a decrease in the percentage of void area of the solder joint. Voiding declined as the preform volume increased as a percentage of the total volume of the solder joint. The presence or absence of the preform was the most significant factor with respect to voiding.

### EXAMPLE 2

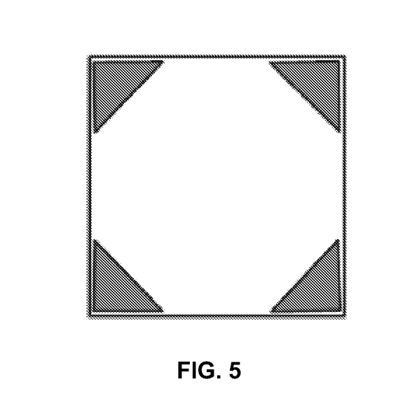

A void reduction preform in accordance with one or more embodiments was formed as illustrated in FIG. 5. The dark areas represent printed solder paste while the white area represents a flux coated solder preform. These flux coated preforms provided repeatable results during testing.

Having now described some illustrative embodiments, it should be apparent to those skilled in the art that the foregoing is merely illustrative and not limiting, having been presented by way of example only. Numerous modifications and other embodiments are within the scope of one of ordinary skill in the art and are contemplated as falling within the scope of the invention. In particular, although many of the examples presented herein involve specific combinations of method acts or system elements, it should be understood that those acts and those elements may be combined in other ways to accomplish the same objectives.

It is to be appreciated that embodiments of the devices, systems and methods discussed herein are not limited in application to the details of construction and the arrangement of components set forth in this description or in the accompanying drawings. The devices, systems and methods are capable of implementation in other embodiments and of being practiced or of being carried out in various ways. Examples of specific implementations are provided herein for illustrative purposes only and are not intended to be limiting. In particular, acts, elements and features discussed in connection with any one or more embodiments are not intended to be excluded from a similar role in any other embodiments.

Those skilled in the art should appreciate that the parameters and configurations described herein are exemplary and that actual parameters and/or configurations will depend on the specific application in which the systems and techniques of the invention are used. Those skilled in the art should also recognize or be able to ascertain, using no more than routine experimentation, equivalents to the specific embodiments of the invention. It is therefore to be understood that the embodiments described herein are presented by way of example only and that, within the scope of the appended claims and equivalents thereto, the invention may be practiced otherwise than as specifically described.

Moreover, it should also be appreciated that the invention is directed to each feature, system, subsystem, or technique described herein and any combination of two or more features, systems, subsystems, or techniques described herein and any combination of two or more features, systems, subsystems, and/or methods, if such features, systems, subsystems, and techniques are not mutually inconsistent, is considered to be within the scope of the invention as embodied in the claims. Further, acts, elements, and features discussed only in connection with one embodiment are not intended to be excluded from a similar role in other embodiments.

The phraseology and terminology used herein is for the purpose of description and should not be regarded as limiting. As used herein, the term “plurality” refers to two or more items or components. The terms “comprising,” “including,” “carrying,” “having,” “containing,” and “involving,” whether in the written description or the claims and the like, are open-ended terms, i.e., to mean “including but not limited to.” Thus, the use of such terms is meant to encompass the items listed thereafter, and equivalents thereof, as well as additional items. Only the transitional phrases “consisting of” and “consisting essentially of,” are closed or semi-closed transitional phrases, respectively, with respect to the claims. Use of ordinal terms such as “first,” “second,” “third,” and the like in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

1. A method of reducing void formation in a solder joint, comprising:
applying a solder paste deposit to a substrate;
placing a solder preform in the solder paste deposit;
disposing a device on the solder preform and the solder paste deposit; and
processing the solder paste deposit and the solder preform to form the solder joint between the device and the substrate.

2. The method of claim 1, wherein the substrate is a printed circuit board and wherein the device is an integrated circuit package.

3. The method of claim 1, wherein the processing step comprises heating the solder paste deposit and the solder preform to a temperature in a range of about 140° C. to about 275° C.

4. The method of claim 1, further comprising a plurality of preforms in the solder paste deposit.

5. The method of claim 1, wherein the solder paste deposit is applied in a thickness greater than or equal to a thickness of the solder preform.

6. The method of claim 1, wherein applying the solder paste deposit to the substrate comprises printing the solder paste in a pattern on the substrate.

7. The method of claim 1, wherein a diameter of the solder preform is between about 1 mm and about 15 mm.

8. The method of claim 1, wherein a thickness of the solder preform is between about 0.025 mm and about 0.2 mm.

9. The method of claim 1, wherein the solder preform comprises at least about 99.9% by weight a pure metal or a pure metal alloy.

10. The method of claim 9, wherein the pure metal or the pure metal alloy comprises at least one of tin, silver, antimony, copper, lead, nickel, indium, palladium, gallium, cadmium, and bismuth.

11. The method of claim 1, wherein the solder preform is substantially free of flux.

12. The method of claim 1, wherein the solder joint is characterized by a void space of less than about 40% by area.

13. The method of claim 12, wherein the solder preform contributes about 25% to about 95% of the solder joint by volume after processing.

14. An assembly, comprising:
a printed circuit board;
a device bonded to the printed circuit board; and
a solder joint between the printed circuit board and the device,
wherein about 25% to about 95% of the solder joint by volume comprises a solder preform after processing.

15. The assembly of claim 14, wherein the solder joint comprises at least one of tin, silver, antimony, copper, lead, nickel, indium, palladium, gallium, cadmium, and bismuth.

16. The assembly of claim 14, wherein the solder joint is characterized by a void space of less then about 40% by area.

17. A kit for assembling a device to a printed circuit board, comprising:
a solder paste; and
at least one solder preform having a diameter between about 1 mm and about 15 mm and a thickness between about 0.025 mm and 0.2 mm, the at least one solder preform comprising at least about 99.9% by weight a pure metal or a pure metal alloy.

18. The kit of claim 17, wherein the at least one solder preform is disposed on tape and reel packaging.

19. The kit of claim 17, wherein the at least one solder preform is disposed on a tray for pick and place treatment.

20. The kit of claim 17, wherein the at least one solder preform is packaged in automated-machine-ready packaging.

21. A method of facilitating void reduction in a solder joint, comprising:
providing a solder preform; and
providing instructions to apply the solder preform to a solder paste deposit on a printed circuit board prior to processing to form the solder joint.

22. The method of claim 19, further comprising providing solder paste.

23. A solder joint between a printed circuit board and an integrated circuit package, the solder joint characterized by a void space of less then about 40% by area, wherein about 25% to about 95% of the solder joint by volume comprises a solder preform after processing.
